(19) United States
(12) Patent Application Publication
(10) Pub. No.: US 2024/0222969 A1
(43) Pub. Date: Jul. 4, 2024

(54) POWER SUPPLY SYSTEM FOR SEMICONDUCTOR MANUFACTURING SYSTEM GROUP

(71) Applicant: Tokyo Electron Limited, Tokyo (JP)

(72) Inventor: Naoki MATSUMOTO, Miyagi (JP)

(73) Assignee: Tokyo Electron Limited, Tokyo (JP)

(21) Appl. No.: 18/605,837

(22) Filed: Mar. 15, 2024

Related U.S. Application Data
(63) Continuation of application No. PCT/JP2023/002579, filed on Jan. 27, 2023.

(30) Foreign Application Priority Data
Feb. 10, 2022 (JP) 2022-019863

(51) Int. Cl. H02J 3/00; H01L 21/67

(52) U.S. Cl. CPC H02J 3/00; H01L 21/67167; H01L 21/67173; H01L 21/67178

(57) ABSTRACT

A power supply system includes a power supply, a plurality of power feeding devices coupled to the power supply, a plurality of semiconductor manufacturing systems, and processing circuitry. Each of the plurality of semiconductor manufacturing systems includes a plurality of substrate processing chambers and a power receiving device that wirelessly receives power from a power feeding device of the plurality of power feeding devices. The processing circuitry controls the power distribution unit to adjust a maximum effective power supplied from the power supply to each of the plurality of semiconductor manufacturing systems through the power feeding device based on a power use status in each of the plurality of semiconductor manufacturing systems.

### CROSS-REFERENCE TO RELATED APPLICATIONS

The present application is a continuation of PCT/JP2023/002579, filed Jan. 27, 2023, which claims priority to JP 2022-019863, filed Feb. 10, 2022. The contents of the priority applications are incorporated by reference in their entirety.

### TECHNICAL FIELD

The present disclosure relates to a power supply system for a semiconductor manufacturing system group.

### BACKGROUND

Conventionally, a plasma processing apparatus performs plasma processing on substrates using radio-frequency power. The plasma processing apparatus includes a power supply device that supplies power to a processing chamber through a cable.

### SUMMARY

A power supply system according to one aspect of the present disclosure includes a power supply, a plurality of power feeding devices coupled to the power supply, a plurality of semiconductor manufacturing systems, and processing circuitry. Each of the plurality of semiconductor manufacturing systems includes a plurality of substrate processing chambers and a power receiving device that wirelessly receives power from a power feeding device of the plurality of power feeding devices. The processing circuitry controls the power distribution unit to adjust a maximum effective power supplied from the power supply to each of the plurality of semiconductor manufacturing systems through the power feeding device based on a power use status in each of the plurality of semiconductor manufacturing systems.

### BRIEF DESCRIPTION OF DRAWINGS

FIG. 1 is a schematic diagram of an example power supply system.

FIG. 2 is a schematic plan view of a substrate processing system.

FIG. 3 is a schematic side view of the substrate processing system.

FIG. 4 is a schematic plan view of a coater-developer system showing its internal structure.

FIG. 5 is a schematic side view of the coater-developer system showing its internal structure.

FIG. 6 is a schematic side view of the coater-developer system showing its internal structure.

FIG. 7 is a schematic diagram of another example power supply system.

FIG. 8 is a block diagram of processing circuitry in accordance with the present disclosure.

### DETAILED DESCRIPTION

In the manufacturing processes of semiconductor devices, various processing steps are performed on semiconductor substrates (hereafter simply referred to as substrates) in decompressed processing modules, in each of which a predetermined processing step is performed on the substrates. These processing steps are performed in multiple semiconductor manufacturing systems or a semiconductor manufacturing system group including such systems.

A semiconductor manufacturing system group includes, for example, multiple semiconductor manufacturing systems that operate in parallel in a clean room area. In this case, each of the multiple systems is assigned with a power supply facility that supplies power individually to the corresponding system. The multiple systems may not operate at the same operating rate. Some systems may operate at high rates, and other systems may operate at low rates.

Semiconductor manufacturing systems or a semiconductor manufacturing system group including such systems also includes power supply devices as auxiliary equipment to supply power to multiple units and other components in the semiconductor manufacturing systems. Power is supplied from the power supply device typically through a cable.

However, in the structure using a cable to supply power, a space for laying the cable is to be available, and the cable may restrict the positioning freedom of devices. Additionally, when each of the multiple systems in a semiconductor manufacturing system group is assigned with a power supply facility and when some systems operate at high operating rates and others operate at low operating rates, power may not be shared in a flexible manner among the power supply facilities. This may cause ineffective use of, for example, power from the plant power supply as plant power.

The inventors of the present disclosure have developed technologies for a power supply system that allows efficient operation of power by optimizing power distribution in semiconductor manufacturing systems and a semiconductor manufacturing system group including such systems. Another aspect of the disclosure is directed to a power supply system that uses a smaller space and increases the degree of freedom in device positioning.

The semiconductor manufacturing system and the semiconductor manufacturing system group including such systems will now be described with reference to the drawings. Like reference numerals denote structural elements having substantially the same functions herein and in the drawings. Such components will not be described repeatedly.

### Power Supply System

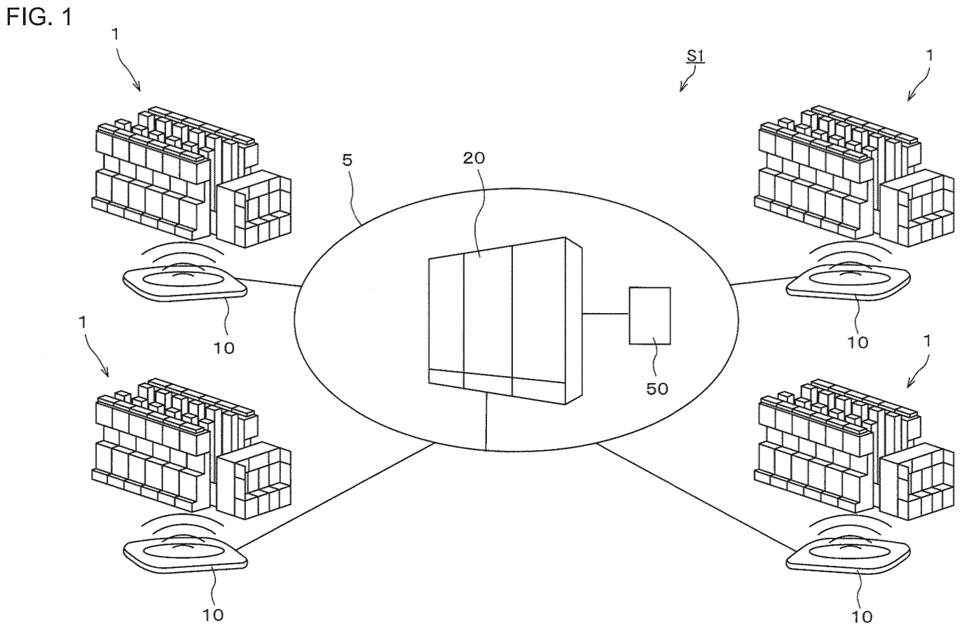

A power supply system S1 according will now be described. FIG. 1 is a schematic diagram of the power supply system S1.

The power supply system S1 includes multiple semiconductor manufacturing systems 1. A power feeding device 10 that is electrically coupled individually to a power cable 5 is located close to each of the semiconductor manufacturing systems 1. The power cable 5 is coupled to a power distribution unit 20 (a plant power supply or an alternating current power supply) that distributes plant power for supplying power. The power feeding devices 10 receive alternating current (AC) power supplied from the power distribution unit 20 through the power cable 5.

The multiple power feeding devices 10 assigned to the respective semiconductor manufacturing systems 1 are coupled to the power distribution unit 20 through the common power cable 5 serving as a single power grid. In other words, the multiple power feeding devices 10 receive power supplied after being distributed from the power distribution unit 20 as appropriate.

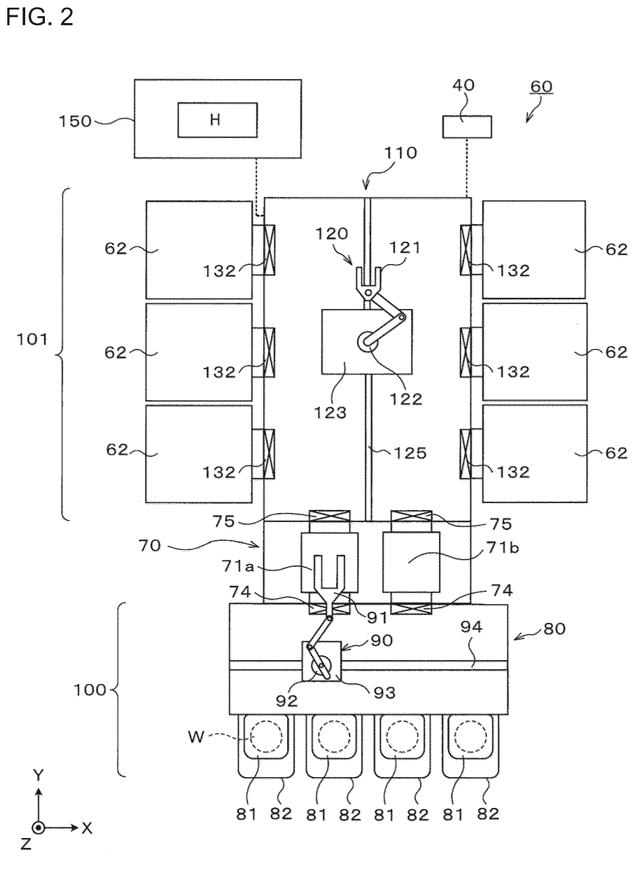

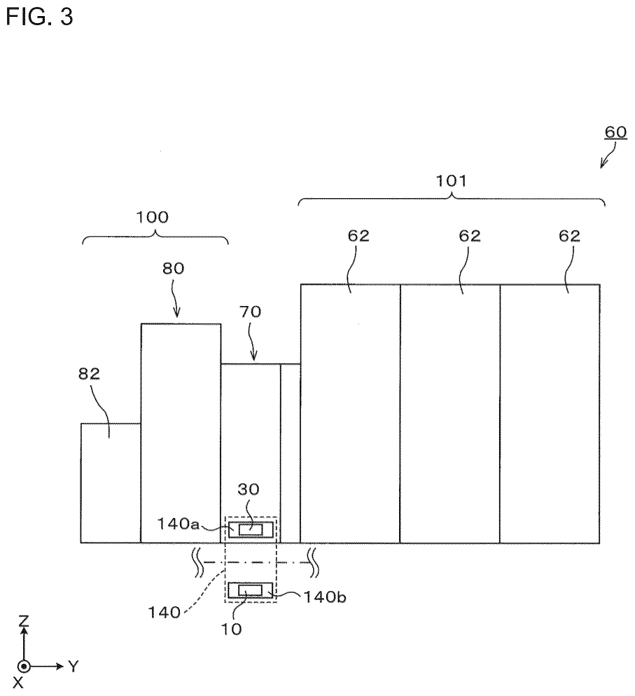

Each semiconductor manufacturing system 1 includes a power receiving device 30 (shown in FIG. 3) to which power is transmitted contactlessly from the corresponding power feeding device 10. Each semiconductor manufacturing system 1 includes a smart meter 40 (shown in FIG. 2) that measures the power used in the system and transmits the measurement data. Based on the data measured with the smart meters 40, the flows of power to the power feeding devices 10 maybe measured to adjust the distribution of power to the power feeding devices 10.

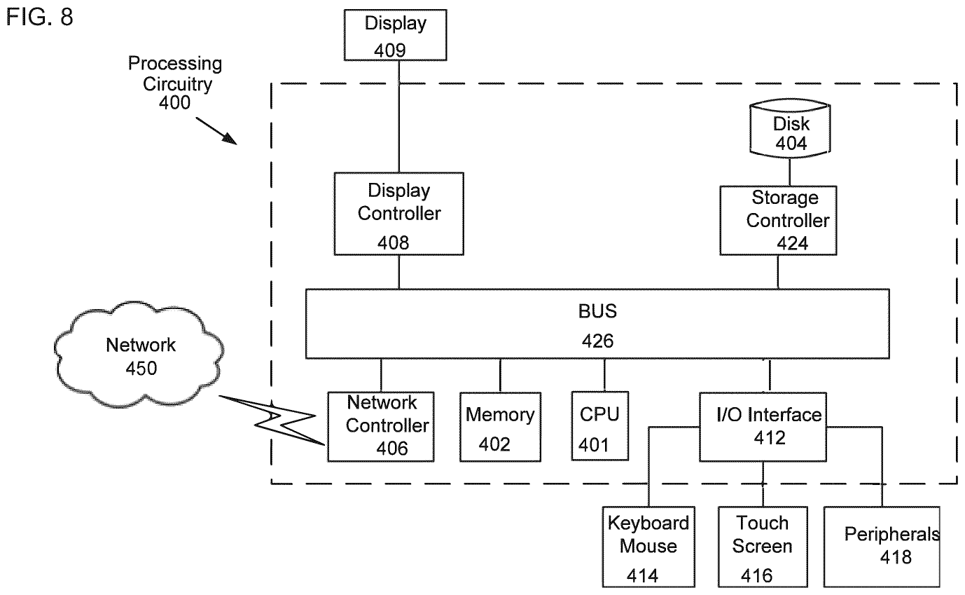

The power distribution unit 20 includes a controller 50 that receives measurement data transmitted from the smart meters 40 and controls the power distribution unit 20. The controller 50 mayanalyze the flows of power to the power feeding devices 10. The controller 50 mayinclude, for example, an autonomous distributed computer that can analyze power flows and optimize power distribution. In an exemplary implementation, controller 50 includes processing circuitry which will be discussed later with respect to FIG. 8.

### First Example Structure of Semiconductor Manufacturing System

An example structure of a substrate processing system that is a plasma processing system including plasma processing apparatuses will now be described as an example of the semiconductor manufacturing system 1. FIG. 2 is a schematic plan view of a substrate processing system 60. FIG. 3 is a schematic side view of the substrate processing system 60. In the example described below, the substrate processing system 60 includes multiple (six) plasma processing apparatuses 62 as substrate processing chambers for performing plasma processing, such as etching or film deposition on substrates W. The structure of modules in the substrate processing system 60 of the disclosure is not limited to this structure and may be selected as appropriate for intended substrate processing.

As shown in FIG. 2, the substrate processing system 60 includes an atmospheric unit 100 and a decompressed unit 101 connected together with a loadlock module 70 between them. The loadlock module 70 includes multiple, or for example, two loadlocks 71a and 71b in the width direction (X-direction) of a loader module 80 (described later). The loadlocks 71a and 71b (hereafter collectively referred to simply as loadlocks 71) connect the internal space of the loader module 80 (described later) in the atmospheric unit 100 and the internal space of a transfer module 110 (described later) in the decompressed unit 101 through substrate transfer ports. Each substrate transfer port can be open and closed with a gate valve 74 or 75.

The loadlocks 71 temporarily hold a substrate W. The loadlocks 71 can switch their internal spaces between the atmospheric pressure and the decompressed atmosphere (vacuum atmosphere). In other words, the loadlock module 70 can transfer substrates W appropriately between the atmospheric unit 100 under the atmospheric pressure and the decompressed unit 101 under the decompressed atmosphere.

The atmospheric unit 100 includes the loader module 80 including a substrate transferrer 90 (described later) and load ports 82 on which front-opening unified pods

(FOUPs) 81 for storing multiple substrates W are placeable. An orienter module may adjust the orientation of a substrate W in a rotation direction and a storage module may store multiple substrates W may be located adjacent to the loader module 80.

The loader module 80 includes an internally rectangular housing with an internal space maintained at the atmospheric pressure. The multiple load ports 82, or for example, four load ports 82, are aligned along one side surface being the long side of the loader module 80 in the negative Y-direction. The loadlocks 71a and 71b in the loadlock module 70 are aligned along the other side surface being the long side of the loader module 80 in the positive Y-direction.

The substrate transferrer 90 for transferring a substrate W is located in the loader module 70. The substrate transferrer 90 includes a transfer arm 91 that holds and moves a wafer W, a rotary stand 92 supporting the transfer arm 91 in a rotatable manner, and a rotary stand base 93 on which the rotary stand 92 is mounted. The loader module 80 includes a guide rail 94 extending in the longitudinal direction (X-direction) of the loader module 80. The rotary stand base 93 is located on the guide rail 94, along which the substrate transferrer 90 is movable.

The decompressed unit 101 includes the transfer module 110 that transfers substrates W inside the decompressed unit 101 and the processing modules (corresponding to plasma processing apparatuses 62) that perform intended processing on the substrates W transferred from the transfer module 110. The transfer module 110 and the processing modules have their internal spaces that can be maintained under the decompressed atmosphere. In an exemplary implementation, multiple (e.g., six) processing modules are connected to the single transfer module 110. Any number of processing modules may be arranged in any manner other than in the present implementation.

The transfer module 110 as a vacuum transfer module is connected to the loadlock module 70. The transfer module 110 transfers, for example, a substrate W loaded into the loadlock 71a in the loadlock module 70 to one processing module in which intended plasma processing is performed on the substrate W. The transfer module 110 then unloads the substrate W to the atmospheric unit 100 through the loadlock 71b in the loadlock module 70. In an exemplary implementation, the transfer module 110 includes a vacuum transfer space and openings. The openings connect with the vacuum transfer space.

A substrate transferrer 120 for transferring a substrate W is located in the transfer module 110. In other words, the substrate transferrer 120 is located in the vacuum transfer space in the vacuum transfer module. The substrate transferrer 120 includes a transfer arm 121 that holds and moves a substrate W, a rotary stand 122 supporting the transfer arm 121 in a rotatable manner, and a rotary stand base 123 on which the rotary stand 122 is mounted. The rotary stand base 123 is located on a guide rail 125 extending in the longitudinal direction (Y-direction) of the transfer module 110, along which the substrate transferrer 120 is movable.

Each processing module (plasma processing apparatus 62) performs plasma processing such as etching or film deposition on a substrate W. The processing module can be selected as appropriate for the intended substrate processing. The processing modules are connected to the transfer module 110 through substrate transfer ports in the side wall surfaces of the transfer module 110. The substrate transfer ports can be open and closed with gate valves 132.

As shown in FIG. 3, the substrate processing system 60 is electrically coupled to a wireless power feeder 140 to supply power to the entire substrate processing system 60. The wireless power feeder 140 includes a power receiver 140a located in the substrate processing system 60 and a power transmitter 140b located outside the substrate processing system 60. The power receiver 140a and the power transmitter 140b may be physically separate from each other. The distance of separation may be, for example, greater than or equal to 40 mm. The power receiver 140a may be located in a lower portion in the loadlock module 70. The power transmitter 140b may be located below the power receiver 140a, on or under the floor on which the substrate processing system 60 is installed. The power receiver 140a may be located on a side surface of the substrate processing system 60. In this case, the power transmitter 140b may be at a position corresponding to the power receiver 140a on the side surface of the substrate processing system 60. In the illustrated example, the power receiver 140a is located in the lower portion in the loadlock module 70, but the power receiver 140a is not limited to this structure. For example, each plasma processing apparatus 62 maybe assigned with a power receiver, or a single power receiver for the entire substrate processing system 60 may distribute power to each plasma processing apparatus 62. Each unit or each component in the plasma processing apparatus 62 maybe assigned with a power receiver to which power is distributed.

The power receiver 140a may include a power receiving device 30, and the power transmitter 140b includes a power feeding device 10. In the wireless power feeder 140, AC power is supplied from the power distribution unit 20 to the power transmitter 140b. The power feeding device 10 then transmits AC power to the power receiving device 30 contactlessly using, for example, magnetic field resonance. The generated AC power is converted to direct current (DC) power with, for example, an AC-DC converter before being supplied. The generated AC power may be supplied without being converted.

Each substrate processing system 60 mayinclude the smart meter 40 that measures the power consumption of the substrate processing system 60 as data and transmits the measurement data to the controller 50. The controller 50 shown in FIG. 1 measures the flows of power to the power feeding devices 10 based on the measurement data transmitted from the smart meters 40 and adjusts the distribution of power to the substrate processing systems 60 (semiconductor manufacturing systems 1) based on the measurement results.

The substrate processing system 60 described above includes a controller 150, as shown in FIG. 2. The controller 150 is, for example, a computer with a central processing unit (CPU) and a memory. The memory may include a program storage which stores programs to control the transfer and processing of substrates W in the substrate processing system 60. The controller 150 may measure, in cooperation with the controller 50 described above, the flow of power to the power feeding device 10 based on the measurement data from the smart meter 40 and adjust the distribution of power to the substrate processing system 60 based on the measurement results. The above programs may be pre-recorded on a computer-readable storage medium H and installed in the controller 150 from the storage medium H, or may be obtained through communication and installed in the controller 150. In an exemplary implementation, controller 150 may include processing circuitry, which will be discussed later with respect to FIG. 8.

### Second Example Structure of Semiconductor Manufacturing System

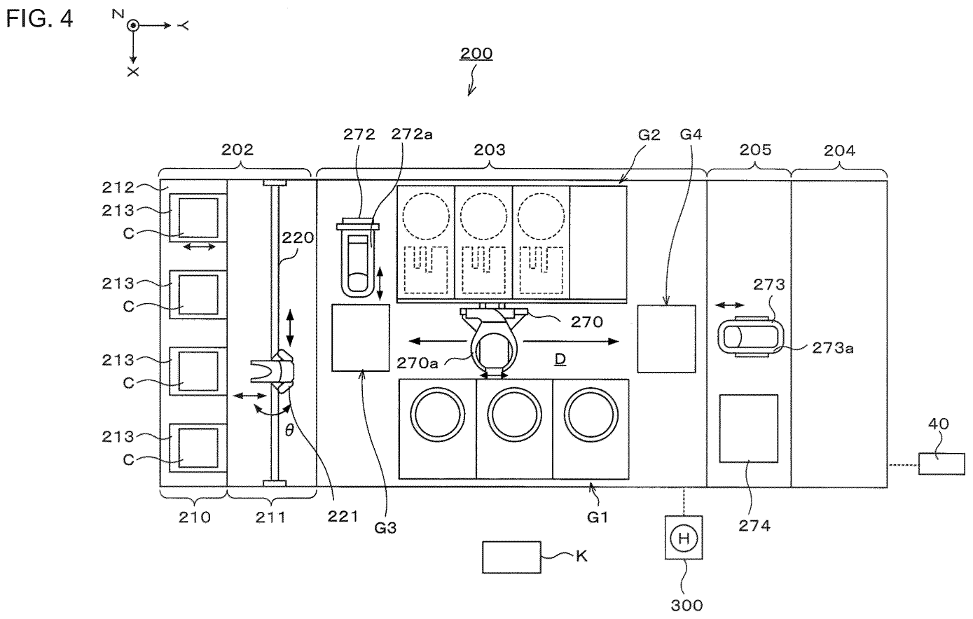

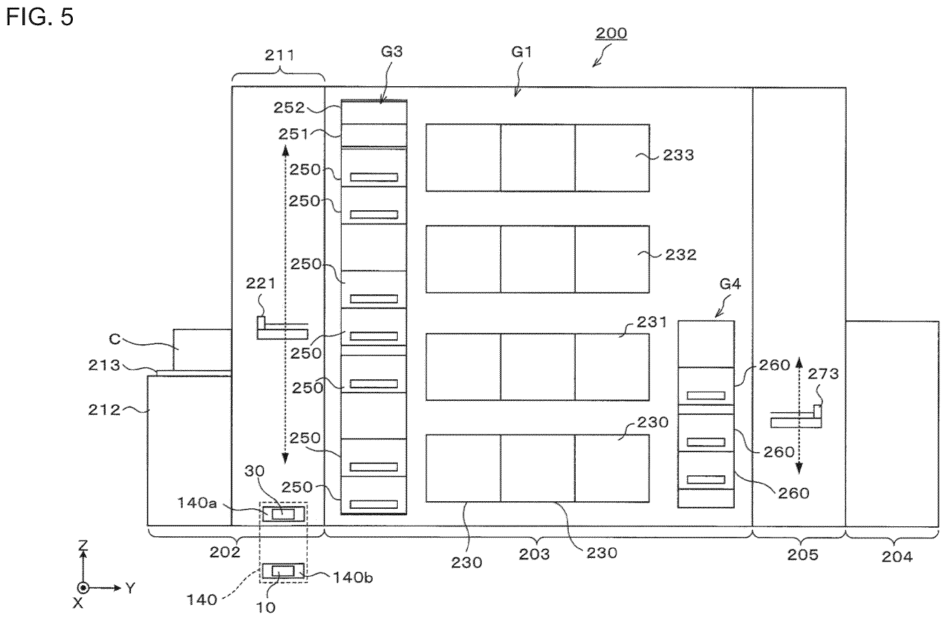

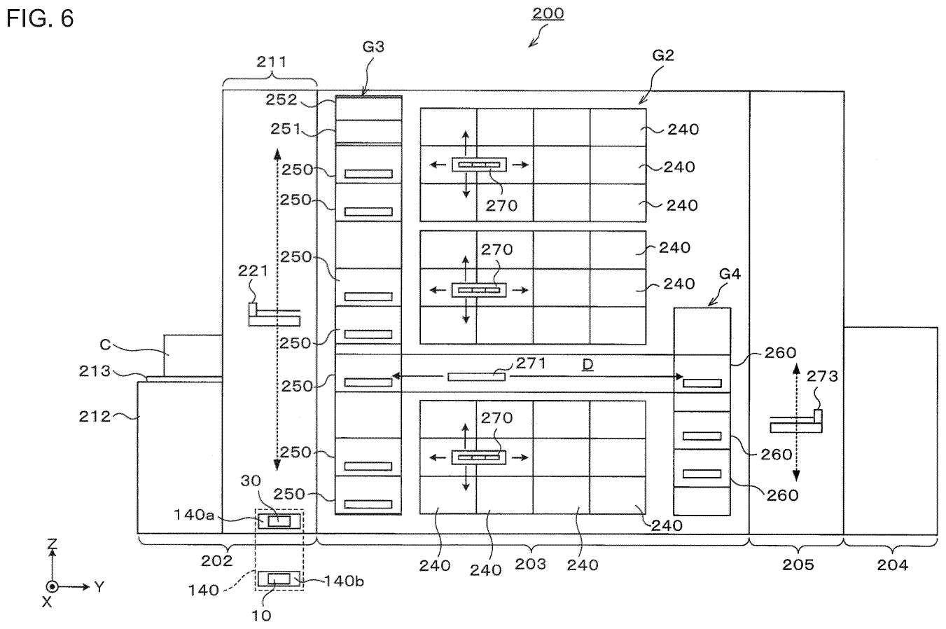

The semiconductor manufacturing system 1 is not limited to the plasma processing system including the plasma processing apparatuses described above, but may be a system that performs various types of substrate processing. As another example of the semiconductor manufacturing system 1, a coater-developer system 200 for forming an underlayer film, an intermediate layer film, and a resist film on a substrate W and developing the resist film after exposure will now be described. FIG. 4 is a schematic plan view of the coater-developer system 200 showing its internal structure. FIGS. 5 and 6 are schematic side views of the coater-developer system 200 showing its internal structure.

As shown in FIG. 4, the coater-developer system 200 includes a cassette station 202 into and from which cassettes containing multiple substrates W are loaded and unloaded, and a processing station 203 including multiple processing apparatuses for performing each processing step in coating and developing. The coater-developer system 200 includes the cassette station 202, the processing station 203, an exposure apparatus 204, and an interface station 205 adjacent to the processing station 203, all of which are connected integrally. The interface station 205 transfers substrates W to and from the exposure apparatus 204.

The cassette station 202 is, for example, divided into a cassette loader-unloader unit 210 and a substrate transfer unit 211. For example, the cassette loader-unloader unit 210 is located at the end of the coater-developer system 200 in the negative Y-direction (leftward in

FIG. 1). The cassette loader-unloader unit 210 includes a cassette support 212. The cassette support 212 supports multiple, or for example, four mount plates 213. The mount plates 213 are aligned in the horizontal direction being X-direction (vertical direction in FIG. 1). Cassettes C can be placed on the mount plates 213 before the cassettes C are loaded to or unloaded from the coater-developer system 200 from or to outside.

The substrate transfer unit 211 includes a substrate transferrer 221 movable along a transfer path 220 extending in X-direction as shown in FIG. 4. The substrate transferrer 221 is also movable in the vertical direction and about the vertical axis (θ-direction), and can transfer substrates W between cassettes C on the mount plates 213 and transferrer-receivers in a third block G3 (described later) in the processing station 203.

The processing station 203 includes multiple, or for example, first to fourth blocks G1, G2, G3, and G4 including various apparatuses. For example, the first block G1 is located adjacent to the front surface of the processing station 203 (in the positive X-direction in FIG. 4), and the second block G2 is located adjacent to the rear surface of the processing station 203 (in the negative X-direction in FIG. 4). The third block G3 in the processing station 203 is located adjacent to the cassette station 202 (in the negative Y-direction in FIG. 4), and the fourth block G4 in the processing station 203 is located adjacent to the interface station 205 (in the positive Y-direction in FIG. 4).

The first block G1 includes liquid processing apparatuses as processing apparatuses. As shown in FIG. 5, for example, developing apparatuses 230, underlayer forming apparatuses 231, intermediate layer forming apparatuses 232, and resist film forming apparatuses 233 are arranged in this order from the bottom. In the developing apparatus 230, a substrate W with a resist film is developed by feeding a developer onto the substrate W after exposure. In each underlayer forming apparatus 231, an underlayer film is formed on a substrate W by feeding a coating liquid for forming the underlayer film onto the substrate W.

The underlayer film is, for example, a spin-on carbon (SoC) film. In each intermediate layer forming apparatus 232, an underlayer film is formed on a substrate W by feeding a coating liquid for forming the intermediate layer film onto the substrate W. The intermediate layer film is, for example, a silicon-containing antireflective coating (SiARC) film. In each resist film forming apparatus 233, a resist film is formed on a substrate W by feeding a resist liquid onto the substrate W.

For example, the three developing apparatuses 230 are aligned horizontally, the three underlayer forming apparatuses 231 are aligned horizontally, the three intermediate layer forming apparatuses 232 are aligned horizontally, and the three resist film forming apparatuses 233 are aligned horizontally. Any numbers of developing apparatuses 230, underlayer forming apparatuses 231, intermediate layer forming apparatuses 232, and resist film forming apparatuses 233 may be arranged in any manner.

In the developing apparatuses 230, the underlayer forming apparatuses 231, the intermediate layer forming apparatuses 232, and the resist film forming apparatuses 233, for example, a predetermined processing liquid is applied onto substrates W by spin coating. In spin coating, for example, a processing liquid is discharged from a coating nozzle onto a substrate W that is being rotated. The processing liquid thus spreads over the surface of the substrate W. A fluid supply unit as a fluid feeder may be located close to the intermediate layer forming apparatuses 232.

In the second block G2, for example, as shown in FIG. 6, heat processing apparatuses 240 that perform a heat process including heating and cooling on substrates W are aligned vertically and horizontally. Each heat processing apparatus 240 performs a predetermined heat process on a substrate W, followed immediately by cooling. The heat processing apparatuses, for example, each include a heating section and a cooling section adjacent to each other. The heating section has a heating plate in a heating chamber, and the cooling section has a cooling plate that also serves as a transfer member to deliver and receive a substrate W to and from the heating plate. Any number of heat processing apparatuses 240 may be arranged in any manner. The heat processing apparatuses 240 include heat processing apparatuses for heating an underlayer film, heat processing apparatuses for heating an intermediate layer film, and heat processing apparatuses for post apply bake (PAB).

In the heat processing apparatus 240 for heating an underlayer film, a substrate W with an underlayer film formed in the underlayer forming apparatus 231 is heated to harden the underlayer film. In the heat processing apparatus 240 for heating an intermediate layer film, a substrate W with an intermediate layer film formed in the intermediate layer forming apparatus 232 is heated to harden the intermediate layer film. In the heat processing apparatus 240 for PAB, a substrate W with a resist film formed in the resist film forming apparatus 233 is heated to harden the resist film before exposure.

The third block G3 includes multiple transferrer-receivers 250 on which inspection devices 251 and 252 are installed.

As shown in FIG. 4, a substrate transfer area D is defined by the first to fourth blocks G1 to G4. A substrate transferrer 270 is, for example, located in the substrate transfer area D.

The substrate transferrer 270 includes, for example, a transfer arm 270a movable in Y-, front-rear, θ-, and vertical directions. The substrate transferrer 270 can move within the substrate transfer area D and transfer substrates W to predetermined apparatuses in the surrounding first block G1, second block G2, third block G3, and fourth block G4. As shown in FIG. 6, for example, multiple substrate transferrers 270 are located at several levels, and each can transfer substrates W to predetermined apparatuses at substantially the same level in the blocks G1 to G4.

A shuttle transferrer 271 that linearly transfers substrates W between the third block G3 and the fourth block G4 is also located in the substrate transfer area D.

The shuttle transferrer 271 is, for example, linearly movable in Y-direction in FIG. 6. The shuttle transferrer 271 can move in Y-direction while supporting a substrate W to transfer the substrate W between the transferrer-receiver 250 in the third block G3 and the transferrer-receiver 260 in the fourth block G4 that are at substantially the same level.

As shown in FIG. 4, a substrate transferrer 272 is located in the negative X-direction from the third block G3. The substrate transferrer 272 includes, for example, a transfer arm 272a movable in the front-rear, θ-, and vertical directions. The substrate transferrer 272 can move vertically while supporting a substrate W to transfer the substrate W to the transferrer-receiver 250 in the third block G3.

The interface station 205 includes a substrate transferrer 273 and a transferrer-receiver 274. The substrate transferrer 273 includes, for example, a transfer arm 273a movable in Y-, θ-, and vertical directions. The substrate transferrer 273 can, for example, support a substrate W with the transfer arm 273a and transfer the substrate W between the transferrer-receivers 260, the transferrer-receiver 274, and the exposure apparatus 204 in the fourth block G4.

The coater-developer system 200 is further combined with a film thickness measurement device K. The film thickness measurement device K is a measurement device that measures film thickness by, for example, applying a laser beam onto the surface of a substrate W in a measurement chamber.

As shown in FIGS. 5 and 6, the coater-developer system 200 is electrically coupled to a wireless power feeder 140 that supplies power to the entire coater-developer system 200. The wireless power feeder 140 includes a power receiver 140a located in the coater-developer system 200 and a power transmitter 140b located outside the coater-developer system 200. The power receiver 140a and the power transmitter 140b may be physically separate from each other. The distance of separation may be, for example, greater than or equal to 40 mm. The power receiver 140a may be located in a lower portion in the substrate transfer unit 211. The power transmitter 140b may be located below the power receiver 140a, on or under the floor on which the coater-developer system 200 is installed. The power receiver 140a may be located on a side surface of the coater-developer system 200. In this case, the power transmitter 140b may be at a position corresponding to the power receiver 140a on the side surface of the coater-developer system 200. In the illustrated example, the power receiver 140a is located in the lower portion in the substrate transfer unit 211, but the power receiver 140a is not limited to this structure. For example, each unit or each component in the coater-developer system 200 may be assigned with a power receiver, or a single power receiver for the entire coater-developer system 200 may distribute power to each unit or each component. The coater-developer system 200 may include a smart meter 40 that measures the power consumption of the coater-developer system 200 as data and transmits the measurement data to the controller 50. The controller 50 shown in FIG. 1 measures the flows of power to the power feeding devices 10 based on the measurement data transmitted from the smart meters 40 and adjusts the distribution of power to the coater-developer system 200 (semiconductor manufacturing systems 1) based on the measurement results.

The coater-developer system 200 described above includes a controller 300 as shown in FIG. 4. The controller 300 is, for example, a computer with a CPU and a memory. The controller 300 may include a program storage which stores programs to control various types of processing on substrates W in the coater-developer system 200. The controller 300 may measure, in cooperation with the controller 50 described above, the flow of power to the power feeding device 10 based on the measurement data from the smart meter 40 and adjust the distribution of power to the coater-developer system 200 based on the measurement results. The above programs may be pre-recorded on a computer-readable storage medium H and installed in the controller 300 from the storage medium H. The above storage medium H may be transitory or non-transitory. In an exemplary implementation, controller 300 may include processing circuitry, which will be discussed later with respect to FIG. 8.

### Power Supply Method

In the power supply system S1 shown in FIG. 1, multiple systems are on the same power grid, such as the substrate processing systems 60 described with reference to FIGS. 2 and 3 or the coater-developer systems 200 described with reference to FIGS. 4 to 6 as examples of the semiconductor manufacturing system 1. With some systems operating at high operating rates and other systems operating at low operating rates, power may be distributed not equally to every system on the grid.

AC power is distributed from the power distribution unit 20 to the power feeding devices 10 assigned to the respective systems through the power cable 5 serving as a single power grid. The power to be supplied to each power feeding device 10 is determined based on the measurement data from the smart meter 40 included in the corresponding system. For example, power consumption may be predicted based on power use measured with the smart meters 40 as data, and power may be supplied based on the predictions.

The power distribution unit 20 mayinclude the controller 50 that receives measurement results transmitted from the smart meters 40 and controls the power distribution unit 20. The controller 50 receives the measurement data transmitted from the smart meters 40 in the systems and analyzes the measurement data. Based on the analysis, the distribution of power to the multiple semiconductor manufacturing systems 1 in the power supply system S1 is adjusted. The maximum effective power supplied from the power distribution unit 20 to each semiconductor manufacturing system 1 may be adjusted based on the status of use of power in the semiconductor manufacturing systems 1. For example, the power to be allocated to a system out of operation may be distributed to another system in operation to optimize power supply. The controller 50 may predict power consumption based on the substrate transfer schedules and processing schedules in the semiconductor manufacturing systems 1, and adjust the maximum effective power supplied from the power distribution unit 20 to each semiconductor manufacturing system 1 based on the predicted power consumption and the status of use of power in the semiconductor manufacturing systems 1.

The maximum effective power supplied to each semiconductor manufacturing system 1 may be adjusted without changing the rated power of the power distribution unit 20. The rated power of the power distribution unit 20 may be determined, for example, to be equal to the sum of the rated powers of the coupled multiple semiconductor manufacturing systems 1.

The maximum effective power supplied to each semiconductor manufacturing system 1 may be less than the rated power of the semiconductor manufacturing system 1. In an example, the maximum effective power may be controlled to be less than 70% of the rated power of each semiconductor manufacturing system 1. The maximum effective power supplied to each semiconductor manufacturing system 1 may be adjusted not to exceed the actual power use in the semiconductor manufacturing system 1. As the values of actual power use, for example, the measurement data transmitted from the smart meters 40 may be used.

The rated power of each semiconductor manufacturing system 1 may be determined with various factors. For example, the rated power may be determined based on the number of substrate processing chambers (the plasma processing apparatuses 62, the developing apparatuses 230, the underlayer forming apparatuses 231, the intermediate layer forming apparatuses 232, and the resist film forming apparatuses 233 described above) included in the semiconductor manufacturing system 1.

### Advantages and Effects of Disclosure

In the power supply system S1, power is supplied from the power distribution unit 20 to the multiple semiconductor manufacturing systems 1 (specifically, a semiconductor manufacturing system group) through the power cable 5 serving as a single power grid in a clean room area. Each semiconductor manufacturing system 1 includes the smart meter 40 (not shown in FIG. 1) that measures the power used in the system and transmits the measurement data, and power is supplied based on the measurement data. The smart meters 40 in the semiconductor manufacturing systems 1 in combination allow efficient use of power by optimizing power distribution.

For example, optimizing the distribution of power supplied to the multiple semiconductor manufacturing systems 1 based on data measured with the smart meters 40 improves the efficiency of power use and reduces the electricity cost. The power allocated to a system out of operation is distributed to another system in operation to reduce the electricity cost.

Additionally, the power supply system S1 includes the power feeding devices 10 that are electrically coupled to the power cable 5 and located close to the semiconductor manufacturing systems 1. Each semiconductor manufacturing system 1 includes the power receiving device 30 to which power is transmitted contactlessly from the power feeding device 10. In other words, power is supplied to each semiconductor manufacturing system 1 wirelessly. This reduces or eliminates wiring for coupling between the semiconductor manufacturing systems 1 and the power distribution unit 20, as well as their peripheral wiring. This reduces the spaces used by the devices and increases the degree of freedom in device positioning.

Implementations disclosed herein are illustrative in all aspects and should not be construed to be restrictive. The components in the above disclosure may be eliminated, substituted, or modified in various forms without departing from the spirit and scope of the appended claims. For example, the components may be combined as appropriate. These combinations produce the same advantageous effects, as well as other advantageous effects that are apparent to those skilled in the art from the implementations described herein.

The effects described herein are merely illustrative or exemplary and are not limitative. In other words, the technique according to the disclosure may produce other effects that will be apparent to those skilled in the art from the present disclosure, in addition to or in place of the above effects.

For example, in the power supply system S1, the semiconductor manufacturing system 1 mayinclude a power storage that stores power from the power receiving device 30. The power storage may be, for example, a capacitor or a battery that stores DC power obtained by converting AC power from the power receiving device 30 with, for example, a converter (not shown). The stored power is supplied to the semiconductor manufacturing system 1 or at least one element such as a unit or a component in the semiconductor manufacturing system 1 that uses power to operate. The power is then used to drive the system or the element.

The manufacturing system 1 mayinclude a power storage to further reduce the electricity cost in addition to producing the effects described above. In other words, storing power at a lower cost in the power storage during specific hours (e.g., nighttime) and using the power to drive the semiconductor manufacturing system 1 and units or components in the system reduce the electricity cost.

In the power supply system S1, power is transmitted contactlessly from the power feeding device 10 to the power receiving device 30, and power is supplied to each semiconductor manufacturing system 1 wirelessly. However, the structure according is not limited to this, and power may be transmitted from the power feeding device 10 to the power receiving device 30 with a wire.

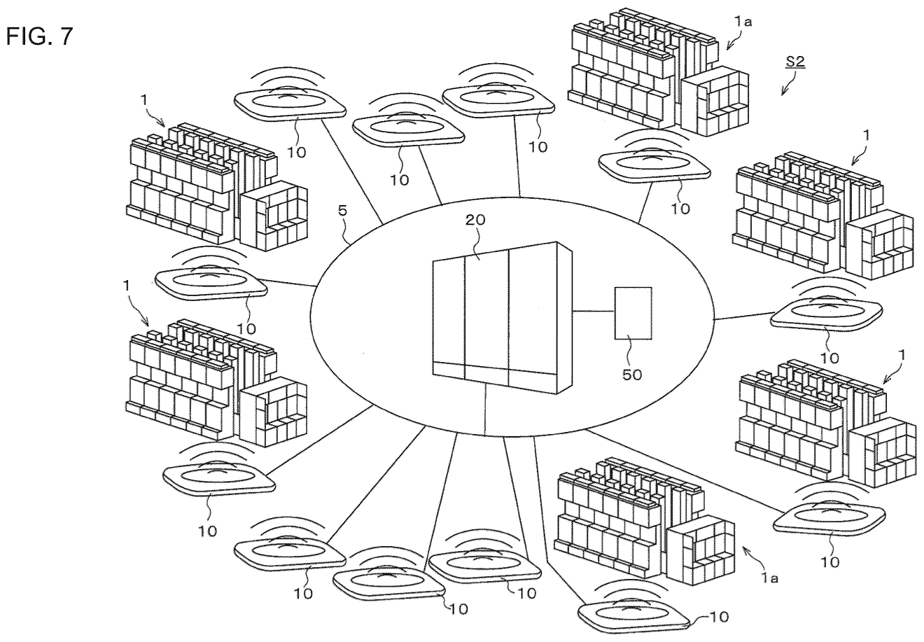

A power supply system S2 will now be described. FIG. 7 is a schematic diagram of a power supply system S2. In the power supply system S2, like reference numerals denote structural elements having substantially the same functions as in the power supply system S1. Such elements may not be described repeatedly.

The power supply system S2 includes multiple semiconductor manufacturing systems 1 and at least one additional semiconductor manufacturing system 1a, unlike in the power supply system S1. A power feeding device 10 that is electrically coupled individually to a power cable 5 is located close to each of the semiconductor manufacturing systems 1 and 1a. The power cable 5 is coupled to a power distribution unit 20 (a plant power supply or an AC power supply) that distributes plant power for supplying power. The power feeding devices 10 receive AC power supplied from the power distribution unit 20 through the power cable 5.

The number of power feeding devices 10 may be greater than the number of semiconductor manufacturing systems 1 and 1a. As shown in FIG. 7, each of the multiple semiconductor manufacturing systems 1 and 1a is assigned with one power feeding device 10, and some of the power feeding devices 10 may be assigned to none of the semiconductor manufacturing systems 1 or 1a. In this structure, each of the semiconductor manufacturing systems 1 and 1a may wirelessly receive power from any one of the power feeding devices 10 through a power receiving device 30. Increasing the number of power feeding devices 10 in this manner allows easy relocation of the semiconductor manufacturing systems 1 and 1a, thus increasing the degree of freedom in changing the layout.

The sum of the maximum effective powers supplied to the multiple semiconductor manufacturing systems 1 and the additional semiconductor manufacturing systems 1a may be less than the rated power of the power distribution unit 20.

An example of power supply will now be described. Unlike the power supply system S1, the power supply system S2 includes an additional number of semiconductor manufacturing systems. In an example, each of the semiconductor manufacturing systems 1 and 1a includes 12 substrate processing chambers, each of which can use the maximum power of 1. In this case, the semiconductor manufacturing systems 1 and 1a each have the maximum power use of 12. The power supply system S1 includes four semiconductor manufacturing systems 1. Thus, the entire system has the maximum power use of 48. In this case, the power distribution unit 20 has the rated power of 48.

However, each substrate processing chamber may have the actual power use that may not be equal to the maximum value. For example, each chamber may have the power use of 0.6. In this case, the four semiconductor manufacturing systems 1 together have the power use of 28.8. For example, with two additional semiconductor manufacturing systems 1a, the total power use is 43.2. More specifically, the structure (power supply system S2) including the additional semiconductor manufacturing systems 1a has the power use that does not exceed 48, which is the rated power of the power distribution unit 20 in the base structure. The power supply system S2 thus allows addition of semiconductor manufacturing systems 1a without changing the rated power of the existing equipment to achieve efficient power supply.

FIG. 8 is a block diagram of processing circuitry that performs computer-based operations in accordance with the present disclosure. FIG. 8 illustrates processing circuitry 400 of controller 50, controller 150 and controller 300.

Processing circuitry 400 is used to control any computer-based and cloud-based control processes, descriptions or blocks in flowcharts can be understood as representing modules, segments or portions of code which include one or more executable instructions for implementing specific logical functions or steps in the process, and alternate implementations are included within the scope of the present disclosure in which functions can be executed out of order from that shown or discussed, including substantially concurrently or in reverse order, depending upon the functionality involved, as would be understood by those skilled in the art. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are configured or programmed, using one or more programs stored in one or more memories, to perform the disclosed functionality. Processors are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality.

In FIG. 8, the processing circuitry 400 includes a CPU 401 which performs one or more of the control processes discussed in this disclosure. The process data and instructions may be stored in memory 402. These processes and instructions may also be stored on a storage medium disk 404 such as a hard drive (HDD) or portable storage medium or may be stored remotely. Further, the claimed advancements are not limited by the form of the computer-readable media on which the instructions of the inventive process are stored. For example, the instructions may be stored on CDs, DVDs, in FLASH memory, RAM, ROM, PROM, EPROM, EEPROM, hard disk or any other non-transitory computer readable medium of an information processing device with which the processing circuitry 400 communicates, such as a server or computer. The processes may also be stored in network based storage, cloud-based storage or other mobile accessible storage and executable by processing circuitry 400.

Further, the claimed advancements may be provided as a utility application, background daemon, or component of an operating system, or combination thereof, executing in conjunction with CPU 401 and an operating system such as Microsoft Windows, UNIX, Solaris, LINUX, Apple MAC-OS, Apple iOS and other systems.

The hardware elements in order to achieve the processing circuitry 400 may be realized by various circuitry elements. Further, each of the functions of the present disclosure may be implemented by circuitry, which includes one or more processing circuits. A processing circuit includes a particularly programmed processor, for example, processor (CPU) 401, as shown in FIG. 8. A processing circuit also includes devices such as an application specific integrated circuit (ASIC) and conventional circuit components arranged to perform the recited functions.

In FIG. 8, the processing circuitry 400 may be a computer or a particular, special-purpose machine. Processing circuitry 400 is programmed to execute processing of controller 50, controller 150 and controller 300.

Alternatively, or additionally, the CPU 401 may be implemented on an FPGA, ASIC, PLD or using discrete logic circuits, as one of ordinary skill in the art would recognize. Further, CPU 401 may be implemented as multiple processors cooperatively working in parallel to perform the instructions of the inventive processes described above.

The processing circuitry 400 in FIG. 8 also includes a network controller 406, such as an Ethernet PRO network interface card, for interfacing with network 450. As can be appreciated, the network 450 can be a public network, such as the Internet, or a private network such as a local area network (LAN) or wide area network (WAN), or any combination thereof and can also include Public Switched Telephone Network (PSTN) or Integrated Services Digital Network (ISDN) sub-networks. The network 450 can also be wired, such as an Ethernet network, universal serial bus (USB) cable, or can be wireless such as a cellular network including EDGE, 4G and 4G wireless cellular systems. The wireless network can also be Wi-Fi, wireless LAN, Bluetooth, or other wireless form of communication. Additionally, network controller 406 may be compliant with other direct communication standards, such as Bluetooth, a near field communication (NFC), infrared ray or other.

The processing circuitry 400 further includes a display controller 408, such as a graphics card or graphics adaptor for interfacing with display 409, such as a monitor. An I/O interface 412 interfaces with a keyboard and/or mouse 414 as well as a touch screen panel 416 on or separate from display 409. I/O interface 412 also connects to a variety of peripherals 418.

The storage controller 424 connects the storage medium disk 404 with communication bus 426, which may be an ISA, EISA, VESA, PCI, or similar, for interconnecting all of the components of the processing circuitry 400. A description of the general features and functionality of the display 409, keyboard and/or mouse 414, as well as the display controller 408, storage controller 424, network controller 406, and I/O interface 412 is omitted herein for brevity.

The exemplary circuit elements described in the context of the present disclosure may be replaced with other elements and structured differently than the examples provided herein. Moreover, circuitry configured to perform features described herein may be implemented in multiple circuit units (e.g., chips), or the features may be combined in circuitry on a single chipset.

The functions and features described herein may also be executed by various distributed components of a system. For example, one or more processors may execute these system functions, wherein the processors are distributed across multiple components communicating in a network. The distributed components may include one or more client and server machines, which may share processing, in addition to various human interface and communication devices (e.g., display monitors, smart phones, tablets, personal digital assistants (PDAs)). The network may be a private network, such as a LAN or WAN, or may be a public network, such as the Internet. Input to the system may be received via direct user input and received remotely either in real-time or as a batch process. Additionally, some implementations may be performed on modules or hardware not identical to those described. Accordingly, other implementations are within the scope that may be claimed.

The example structures described below may also fall within the technical scope of the disclosure.

(1) A power supply system, comprising:
a power distribution unit;
a plurality of power feeding devices coupled to the power distribution unit;
a plurality of semiconductor manufacturing systems, each of the plurality of semiconductor manufacturing systems including a plurality of substrate processing chambers and a power receiving device configured to wirelessly receive power from a power feeding device of the plurality of power feeding devices; and
a controller configured to control the power distribution unit to adjust a maximum effective power supplied from the power distribution unit to each of the plurality of semiconductor manufacturing systems through the power feeding device based on a status of use of power in each of the plurality of semiconductor manufacturing systems.

(2) The power supply system according to (1), wherein
the maximum effective power supplied to each of the plurality of semiconductor manufacturing systems is adjusted without changing a rated power of the power distribution unit.

(3) The power supply system according to (1) or (2), wherein
the rated power of the power distribution unit is equal to a sum of rated powers of the plurality of semiconductor manufacturing systems.

(4) The power supply system according to any one of (1) to (3), wherein
the maximum effective power supplied to each of the plurality of semiconductor manufacturing systems is less than a rated power of the semiconductor manufacturing system.

(5) The power supply system according to any one of (1) to (4), wherein
the maximum effective power supplied to each of the plurality of semiconductor manufacturing systems is adjusted to avoid exceeding actual power use in the semiconductor manufacturing system.

(6) The power supply system according to any one of (1) to (5), wherein
the maximum effective power supplied to each of the plurality of semiconductor manufacturing systems is controlled to be less than 70% of a rated power of the semiconductor manufacturing system.

(7) The power supply system according to any one of (1) to (6), wherein
the rated power of each of the plurality of semiconductor manufacturing systems is determined based on a number of substrate processing chambers included in the semiconductor manufacturing system.

(8) The power supply system according to any one of (1) to (7), further comprising:
at least one additional semiconductor manufacturing system, the at least one additional semiconductor manufacturing system including a plurality of additional substrate processing chambers and a power receiving device configured to wirelessly receive power from a power feeding device of the plurality of power feeding devices.

(9) The power supply system according to (8), wherein
a sum of maximum effective powers supplied to the plurality of semiconductor manufacturing systems and the at least one additional semiconductor manufacturing system is less than the rated power of the power distribution unit.

(10) The power supply system according to any one of (1) to (9), wherein
the controller predicts power consumption in each of the plurality of semiconductor manufacturing systems based on at least one of a substrate transfer schedule or a processing schedule in the semiconductor manufacturing system, and
controls the power distribution unit to adjust the maximum effective power supplied from the power distribution unit to each of the plurality of semiconductor manufacturing systems through the power feeding device based on the predicted power consumption and a status of use of power in each of the plurality of semiconductor manufacturing systems.

(11) The power supply system according to any one of (1) to (10), wherein
a number of the plurality of power feeding devices is greater than a number of the plurality of semiconductor manufacturing systems.

(12) The power supply system according to any one of (1) to (11), wherein
each of the plurality of semiconductor manufacturing systems includes a smart meter configured to measure power use as data, and
the controller receives the status of use of power in each of the plurality of semiconductor manufacturing systems from the smart meter.

(13) The power supply system according to any one of (1) to (12), wherein
each of the plurality of semiconductor manufacturing systems includes a power storage configured to store power from the power receiving device, and
power is supplied from the power storage to at least one element in the semiconductor manufacturing system.

(14) The power supply system according to (13), wherein
power is supplied to the power storage after alternating current power from the power receiving device is converted to direct current power.

(15) The power supply system according to (13) or (14), wherein
the power storage is a capacitor or a battery.

(16) The power supply system according to any one of (13) to (15), wherein
power is supplied to the power storage during specific hours.

(17) A power supply system, comprising:
a power distribution unit;
a plurality of power feeding devices coupled to the power distribution unit and configured to wirelessly supply power to a semiconductor manufacturing system of a plurality of semiconductor manufacturing systems; and
a controller configured to control the power distribution unit to adjust a maximum effective power supplied from the power distribution unit to each of the plurality of semiconductor manufacturing systems through a corresponding power feeding device of the plurality of power feeding devices based on a status of use of power in each of the plurality of semiconductor manufacturing systems.

(18) A power supply system, comprising:
a power distribution unit;
a plurality of semiconductor manufacturing systems coupled to the power distribution unit, each of the plurality of semiconductor manufacturing systems including a plurality of substrate processing chambers; and
a controller configured to control the power distribution unit to adjust a maximum effective power supplied from the power distribution unit to each of the plurality of semiconductor manufacturing systems based on a status of use of power in each of the plurality of semiconductor manufacturing systems.

1. A power supply system, comprising:
a power supply;
a plurality of power feeding devices coupled to the power supply;
a plurality of semiconductor manufacturing systems, each of the plurality of semiconductor manufacturing systems including a plurality of substrate processing chambers and a power receiving device which is configured to wirelessly receive power from a power feeding device of the plurality of power feeding devices; and
processing circuitry configured to control the power supply to adjust a maximum effective power supplied from the power supply to each of the plurality of semiconductor manufacturing systems through the power feeding device based on a power use status in each of the plurality of semiconductor manufacturing systems.

2. The power supply system according to claim 1, wherein the maximum effective power supplied to each of the plurality of semiconductor manufacturing systems is adjusted without changing a rated power of the power supply.

3. The power supply system according to claim 2, wherein the rated power of the power supply is equal to a sum of rated powers of the plurality of semiconductor manufacturing systems.

4. The power supply system according to claim 3, wherein the maximum effective power supplied to each of the plurality of semiconductor manufacturing systems is less than a rated power of the semiconductor manufacturing system.

5. The power supply system according to claim 3, wherein the maximum effective power supplied to each of the plurality of semiconductor manufacturing systems is adjusted to avoid exceeding actual power use in the semiconductor manufacturing system.

6. The power supply system according to claim 3, wherein the maximum effective power supplied to each of the plurality of semiconductor manufacturing systems is controlled to be less than 70% of a rated power of the semiconductor manufacturing system.

7. The power supply system according to claim 4, wherein the processing circuitry is further configured to determine the rated power of each of the plurality of semiconductor manufacturing systems based on a number of substrate processing chambers included in the semiconductor manufacturing system.

8. The power supply system according to claim 7, further comprising:
at least one additional semiconductor manufacturing system, the at least one additional semiconductor manufacturing system including a plurality of additional substrate processing chambers and a power receiving device configured to wirelessly receive power from a power feeding device of the plurality of power feeding devices.

9. The power supply system according to claim 8, wherein a sum of maximum effective powers supplied to the plurality of semiconductor manufacturing systems and the at least one additional semiconductor manufacturing system is less than the rated power of the power supply.

10. The power supply system according to claim 1, wherein the processing circuitry is further configured to
predict power consumption in each of the plurality of semiconductor manufacturing systems based on at least one of a substrate transfer schedule or a processing schedule in the semiconductor manufacturing system, and
control the power supply to adjust the maximum effective power supplied from the power supply to each of the plurality of semiconductor manufacturing systems through the power feeding device based on the predicted power consumption and a status of use of power in each of the plurality of semiconductor manufacturing systems.

11. The power supply system according to claim 1, wherein a number of the plurality of power feeding devices is greater than a number of the plurality of semiconductor manufacturing systems.

12. The power supply system according to claim 1, wherein
each of the plurality of semiconductor manufacturing systems includes a smart meter configured to measure power use as data, and
the processing circuitry receives the power use status in each of the plurality of semiconductor manufacturing systems from the smart meter.

13. The power supply system according to claim 1, wherein
each of the plurality of semiconductor manufacturing systems includes a power storage configured to store power from the power receiving device, and
power is supplied from the power storage to at least one element in the semiconductor manufacturing system.

14. The power supply system according to claim 13, wherein power is supplied to the power storage after alternating current power from the power receiving device is converted to direct current power.

15. The power supply system according to claim 14, wherein the power storage is a capacitor or a battery.

16. The power supply system according to claim 15, wherein power is supplied to the power storage during specific hours.

17. A power supply system, comprising:
a power supply;
a plurality of power feeding devices coupled to the power supply and configured to wirelessly supply power to a semiconductor manufacturing system of a plurality of semiconductor manufacturing systems; and
processing circuitry configured to control the power supply to adjust a maximum effective power supplied from the power supply to each of the plurality of semiconductor manufacturing systems through a corresponding power feeding device of the plurality of power feeding devices based on a power use status in each of the plurality of semiconductor manufacturing systems.

18. A power supply system, comprising:
a power supply;
a plurality of semiconductor manufacturing systems coupled to the power supply, each of the plurality of semiconductor manufacturing systems including a plurality of substrate processing chambers; and
processing circuitry configured to control the power supply to adjust a maximum effective power supplied from the power supply to each of the plurality of semiconductor manufacturing systems based on a power use status in each of the plurality of semiconductor manufacturing systems.
